(19) United States
(12) Patent Application Publication
(10) Pub. No.: US 2023/0047486 A1
(43) Pub. Date: Feb. 16, 2023

(54) ALLOY FILM ETCH

(71) Applicant: Lam Research Corporation, Fremont, CA (US)

(72) Inventors: Younghee LEE, Pleasanton, CA (US); Daniel PETER, Sunnyvale, CA (US); Samantha SiamHwa TAN, Newark, CA (US)

(21) Appl. No.: 17/792,996

(22) PCT Filed: Jan. 25, 2021
(86) PCT No.: PCT/US2021/014938

§ 371 Date: Jul. 14, 2022

Related U.S. Application Data
(60) Provisional application No. 62/968,400, filed on Jan. 31, 2020.

(51) Int. Cl. H01L 21/033; H01L 21/02; H01L 21/311

(52) U.S. Cl. CPC H01L 21/0337; H01L 21/02164; H01L 21/02186; H01L 21/31116

(57) ABSTRACT

A method for forming etched features in a layer of a first material is provided. A layer of a second material is deposited over the layer of the first material. An alloy layer of the first material and the second material is formed between the layer of the first material and the layer of the second material. The layer of the first material is selectively etched with respect to the alloy layer, using the alloy layer as a hardmask.

### CROSS-REFERENCE TO RELATED APPLICATION

This application claims the benefit of priority of U.S. Application No. 62/968,400, filed Jan. 31, 2020, which is incorporated herein by reference for all purposes.

### BACKGROUND

The background description provided here is for the purpose of generally presenting the context of the present disclosure. Anything described in this background section, and potentially aspects of the written description, are not expressly or impliedly admitted as prior art with respect to the present application.

The present disclosure relates to the formation of semiconductor devices. More specifically, the disclosure relates etching to form semiconductor devices.

For etching silicon oxide (SiO₂), a fluorine containing reactive ion etch may be use. If a reactive ion etch process uses a mask that is too thick, etch resolution is decreased. Some etch processes are not sufficiently selective requiring thicker etch masks.

### SUMMARY

To achieve the foregoing and in accordance with the purpose of the present disclosure, a method for forming etched features in a layer of a first material is provided. A layer of a second material is deposited over the layer of the first material. An alloy layer of the first material and the second material is formed between the layer of the first material and the layer of the second material. The layer of the first material is selectively etched with respect to the alloy layer, using the alloy layer as a hardmask.

In another manifestation, a method for etching a layer of a first material is provided. The method comprises a plurality of cycles, wherein each cycle, comprises depositing a layer of a second material over the layer of the first material, forming an alloy layer of the first material and the second material between the layer of the first material and the layer of the second material. etching away the layer of the second material, and etching away the alloy layer.

In another manifestation, a method for forming an alloy layer with features is provided. An alloy layer is deposited comprising a plurality of cycles, wherein each cycle comprises depositing by atomic layer deposition a layer of a first material and depositing by atomic layer deposition a layer of a second material, wherein the layer of the first material and the layer of the second material form the alloy layer.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-G are schematic cross-sectional views of a stack processed according to an embodiment.

FIG. 3 is a high level flow chart on another embodiment.

FIGS. 4A-D are schematic cross-sectional views of a stack processed according to an embodiment, shown in FIG. 3.

FIG. 5 is a high level flow chart of another embodiment.

FIGS. 6A-H are schematic cross-sectional views of a stack processed according to various embodiments.

FIG. 7 is a more detailed flow chart of a step of etching the alloy layer.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

For etching silicon oxide (SiO₂), a fluorine containing reactive ion etch may be use. If a reactive ion etch process uses a mask that is too thick, etch resolution is decreased. Some etch processes are not sufficiently selective requiring thicker etch masks. One method of improving an etch process is by providing a hardmask that allows a material to be highly selectively etched with respect to the hardmask. An embodiment provides a method for depositing a thin hardmask that allows a substrate, such as SiO₂ to be highly selectively etched with respect to the hardmask.

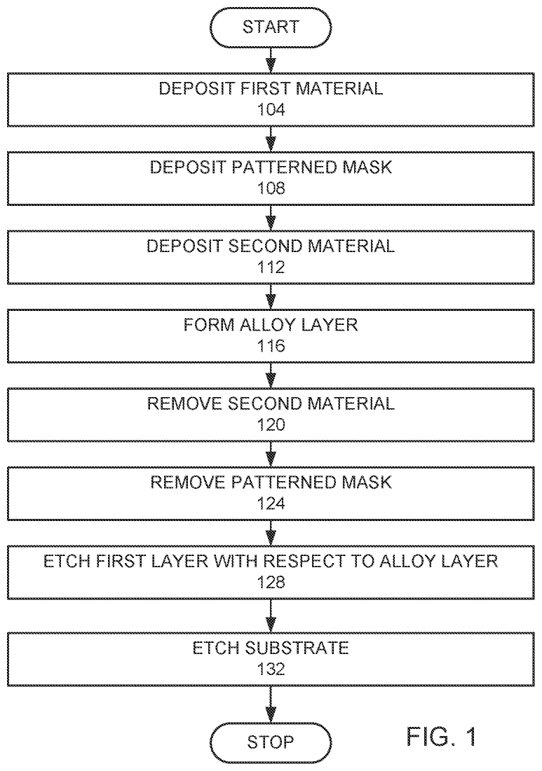

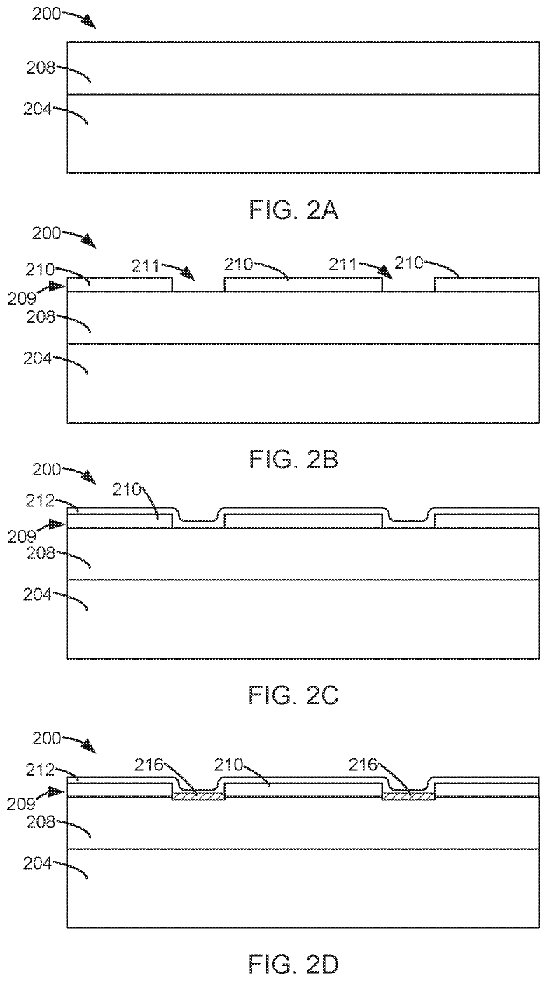

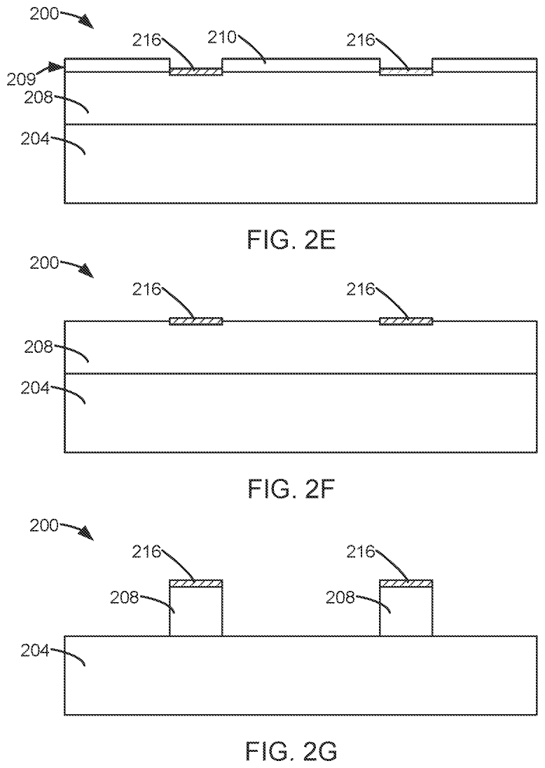

In order to facilitate understanding of an embodiment, FIG. 1 is a high level flow chart of an embodiment. Various embodiments may have more or less steps. In addition, the steps may be performed in different orders or simultaneously. A first material is deposited on a substrate (step 104). FIG. 2A is a schematic cross-sectional view of a stack 200 processed according to an embodiment. In this embodiment, the stack comprises a substrate 204. A first material layer 208 is deposited over the substrate 204. The first material may be any possible material. In this example, the first material is SiO₂. The material may be deposited in any possible way. In this embodiment, the first material is deposited by one of an atomic layer deposition process, a sputtering process, chemical vapor deposition, or a spin-on process. The material may have any possible thickness. In this embodiment, the first material layer 208 has a thickness of between 0.5 nm to 20 nm. The drawings are not shown to scale.

A patterned mask is deposited on the first material layer 208 (step 108). In this example, a patterned mask is formed on the first material layer 208. The patterned mask may be any possible material deposited by any possible manner at any possible thickness. In an embodiment, the patterned mask may be formed by depositing a layer of a mask material and then forming features in the mask material. The patterned mask may be formed by other methods. The patterned mask 209 may be a photoresist mask. FIG. 2B is a schematic cross-sectional view of the stack after the patterned mask 209 has been formed on the first material layer 208. The patterned mask 209 comprises a mask layer 210 with openings forming features 211. The features 211 expose parts of the first material layer 208.

A second material is deposited over the first material layer 208 and the patterned mask 209 (step 112). The second material may be any possible material deposited in any possible manner at any possible thickness. FIG. 2C is a schematic cross-sectional view of the stack 200 after the second material layer 212 has been deposited over the first material layer 208 and the patterned mask 209. In this embodiment, the second material is tin oxide (SnO₂). In this embodiment, the second material layer 212 is deposited by atomic layer deposition or chemical vapor deposition to provide a thin conformal layer. In this embodiment, the second material layer 212 has a thickness of between 0.5 nm to 10 nm.

An alloy layer is formed between the first material layer 208 and the second material layer 212 (step 116). In the specification and claims, an alloy is defined as a material of a mixture comprising a first metal and at least one of a second metal different from the first metal, silicon and carbon. This process may use any possible alloy forming process. In this embodiment, heat is used to form an alloy layer between the first material layer 208 and the second material layer 212. In other embodiments, the first material layer 208 and the second material layer 212 form an alloy without the addition of heat. FIG. 2D is a schematic cross-sectional view of the stack 200 after an alloy layer 216 is formed. The alloy is a tin-silicon-oxide (Sn—Si-Ox) alloy. In this embodiment, an unalloyed first material layer 208 remains and an unalloyed second material layer 212 remains. In other embodiments, all of the second material layer is formed into an alloy.

Since in this embodiment some unalloyed second material layer 212 remains, the unalloyed second material is etched away (step 120). Any process that is able to selectively etch the unalloyed second material may be used. In this example, a hydrogen-based etch is used. In this example, a second material etch gas of hydrogen (H₂) is provided. The second material etch gas is formed into a plasma that etches the second material with respect to the alloy layer 216. FIG. 2E is a schematic cross-sectional view of the stack 200 after the unalloyed second material layer 212 has been etched away.

The patterned mask 209 is removed (step 124). Any process for selectively removing the patterned mask 209 may be used. In this example, an oxygen containing plasma is used to strip the patterned mask 209. FIG. 2F is a schematic cross-sectional view of the stack 200 after the patterned mask 209 has been removed.

The first material is etched with respect to the alloy layer 216 (step 128). Any process that is able to selectively etch the first material with respect to the alloy layer 216 may be used. The patterned alloy layer 216 is used as a hardmask for etching the first material layer 208. In this example, a first etch gas of carbon tetrafluoride (CF₄) or another fluorocarbon-based etch gas is used. FIG. 2G is a schematic cross-sectional view of the stack 200 after the first material layer 208 is etched.

Using the alloy layer 216 as a hardmask may allow for an increased etch selectivity for etching the first material layer 208 with respect to the hardmask of the alloy layer 216. The higher selectivity may allow for a thinner hardmask alloy layer 216. In addition, if the second material layer 212 is deposited by atomic layer deposition or chemical vapor deposition, the second layer may be deposited as a thin conformal layer. Since the resulting alloy layer 216 is formed from the second material layer 212, the resulting alloy layer 216 may also be thin and conformal. Therefore, this embodiment may use the alloy layer 216 to provide a thinner and more conformal hardmask that may provide a highly selective etch of the first material with respect to the hardmask. In some embodiments, the substrate 204 may be etched using either the first material layer 208 or the alloy layer 216 as a mask (step 132).

In various embodiments, if the first material layer 208 is SiO₂, then the second material layer 212 may be at least one of tin (Sn), aluminum (Al), boron (B), molybdenum (Mo), platinum (Pt), and tungsten (W). In such embodiments, a halogen containing recipe may be used to selectively etch the SiO₂ first material layer 208.

In other embodiments, if the first material layer 208 is silicon Si or silicon carbide (SiC), then the second material layer 212 may be at least one of tin (Sn), aluminum (Al), boron (B), molybdenum (Mo), and tungsten (W).

In other embodiments, the first material layer comprises a metal containing material. For example, the metal containing material may comprise titanium nitride (TiN), tantalum nitride (TaN), aluminum nitride (AlN), and tungsten nitride (WNx). In various embodiments, the second material layer comprises, Si, germanium (Ge), and tin (Sn).

In various embodiments, the first material layer 208 is made of a carbon containing material. In such embodiments, the second layer may comprise tin (Sn), Aluminum (Al), Boron (B), Molybdenum (Mo), and tungsten (W).

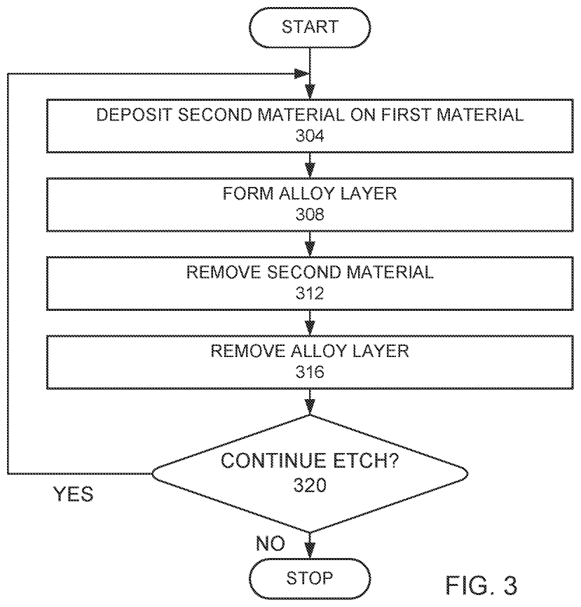

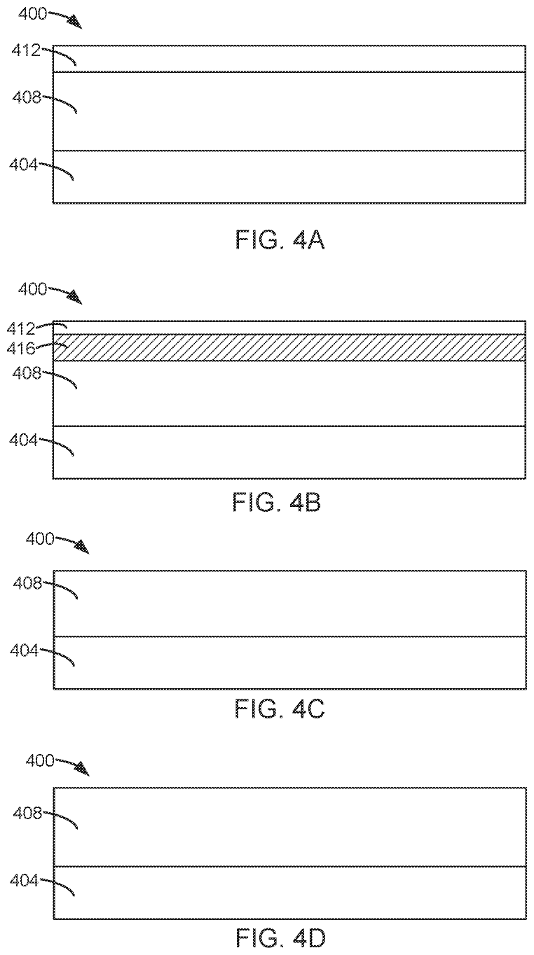

In another embodiment, the alloy layer may be used as a type of an atomic layer etch. FIG. 3 is a high level flow chart of an embodiment that uses the alloy layer for a type of atomic layer etch. Various embodiments may have more or less steps. In addition, the steps may be performed in different orders or simultaneously. A second material is deposited on a first material (step 304). In various embodiments, the first material may be any material and the second material may be any material. These materials may be deposited by any method at any thickness. FIG. 4A is a schematic cross-sectional view of a stack 400 processed according to an embodiment. In this embodiment, the stack comprises a substrate 404 with a first material layer 408 is over the substrate 404. In this example, the first material is SiO₂. The second material forms a second material layer 412. In this embodiment, the second material is titanium oxide (TiO₂). In other embodiments, the second material is tantalum pentoxide (Ta₂O₅), zirconium dioxide (ZrO₂), and hafnium dioxide (HfO₂). In this embodiment, the first material is deposited by atomic layer deposition or chemical vapor deposition to provide a thin conformal layer. In this embodiment, the second material layer 412 has a thickness of between 0.5 nm to 10 nm.

An alloy layer is formed between the first material layer 408 and the second material layer 412 (step 308). In this embodiment, the deposition of the first material layer 408 automatically forms the alloy layer. FIG. 4B is a schematic cross-sectional view of the stack 400 after an alloy layer 416 is formed. The alloy is a titanium-silicon-oxide (Ti—Si-Ox) alloy. In this embodiment, an unalloyed first material layer 408 remains and an unalloyed second material layer 412 remains. In other embodiments, all of the second material layer is formed into an alloy.

Since in this embodiment some unalloyed second material layer 412 remains, the second material layer 412 is etched away (step 312). The alloy layer 416 is removed (step 316). Many possible processes may be used to remove the second material layer 412 and the alloy layer 416 in various embodiments. In this embodiment, a single plasma etch process is used to remove both the unalloyed second material layer 412 (step 312) and to remove the alloy layer 416 (step 316). A plasma formed from a nitrogen trifluoride (NF₃) gas is able to etch titanium oxide of the unalloyed second material layer 412 and etch titanium-silicon-oxide of the alloy layer 416. FIG. 4C is a schematic cross-sectional view of the stack 400 after the unalloyed second material layer 412 and the alloy layer 416 have been etched away. The removal of the alloy layer 416 causes the removal of the first material layer 408 that was formed into part of the alloy layer 416. The alloy layer 416 may be used to enhance etch the first material layer 408. In other embodiments, the removal of the unalloyed second material layer 412 (step 312) and the removal of the alloy layer 416 (step 316) may be performed as separate steps.

In this embodiment, alloying the SiO₂ with Ti, allows the Ti to breakup and change the SiO₂ layer to form the titanium-silicon-oxide alloy. As a result, the titanium-silicon-oxide is able to be etched by the plasma. In other embodiments, tantalum (Ta), zirconium (Zr), or hafnium (HF) are used to breakup and change the SiO₂ layer.

Since some of the first material layer 408 remains, the etch process is continued (step 320), by repeating the cyclical process by going back to the step of depositing a second material layer on the first material layer 408 (step 304). In this embodiment, the cycles are repeated until the first material layer 408 is etched away.

Using the alloy layer 416 as a selective etch layer allows for controlled etch. In addition, since the second material layer 412 is deposited by atomic layer deposition or chemical vapor deposition, the second layer is deposited as a thin conformal layer. Since the resulting alloy layer 416 is formed from the second material layer 412, the resulting alloy layer 416 is also thin and conformal. Therefore, this embodiment allows the etching of the first material layer 408 by thin conformal layers, allowing for a highly selective and conformal etch. In various embodiments, a physical etching requiring a high bias may be needed to etch the first material layer. Forming an alloy layer and then etching the alloy, may use an alloy that can be etched using a chemical etch. Such a chemical etch would use a low or no bias, improving the etch process and reducing damage caused by bombardment. As a result, the alloy layer may be used for an atomic layer etch type of etch with reduced ion bombardment.

In various embodiments, the first material layer 408 is Si or SiC. In such embodiments, the second layer may comprise at least one of Ti, Ta, Zr, nickel (Ni), and cobalt (Co).

In other embodiments, the first material layer comprises a metal containing material. For example, the metal containing material may comprise at least one of TiN, TaN, and AlN In various embodiments, the second material layer comprises at least one of W and Mo.

In various embodiments, the first material layer 208 is made of a carbon containing material. In such embodiments, the second layer may comprise at least one of Si, Ge, Sn, W, and Mo.

In some embodiments, a patterned mask may be placed over the first material layer 408 before etching the first material layer 408. The patterned mask provides a patterned etch of the first material layer 408.

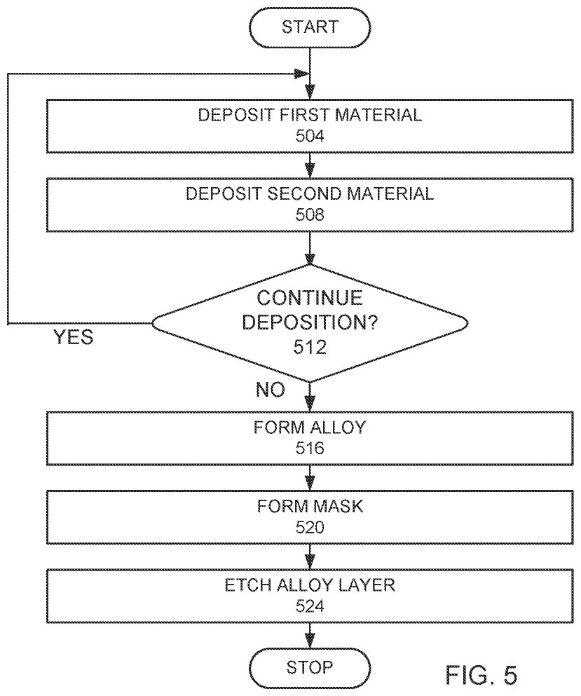

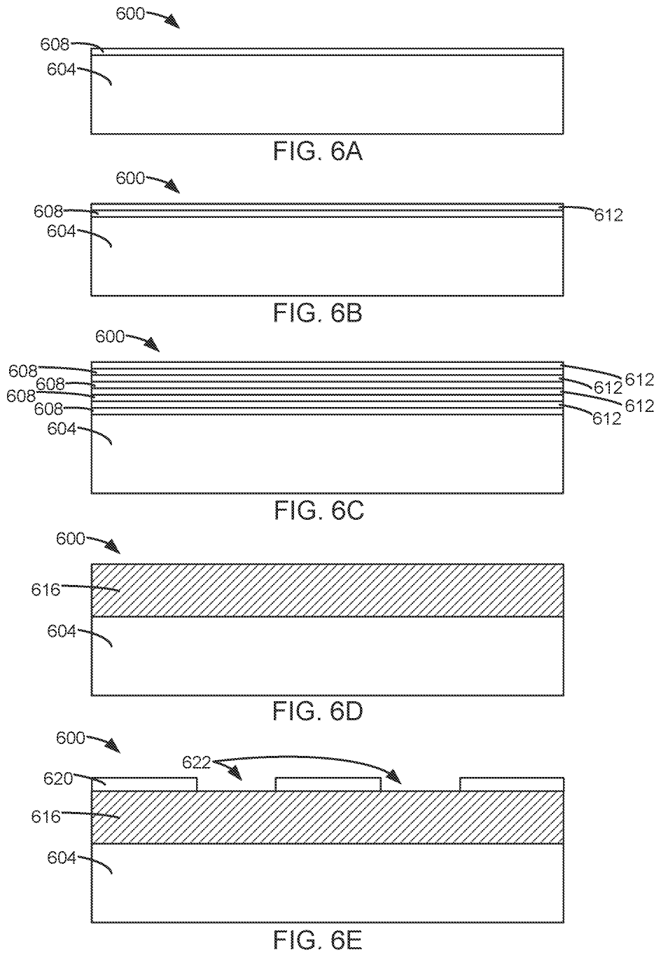

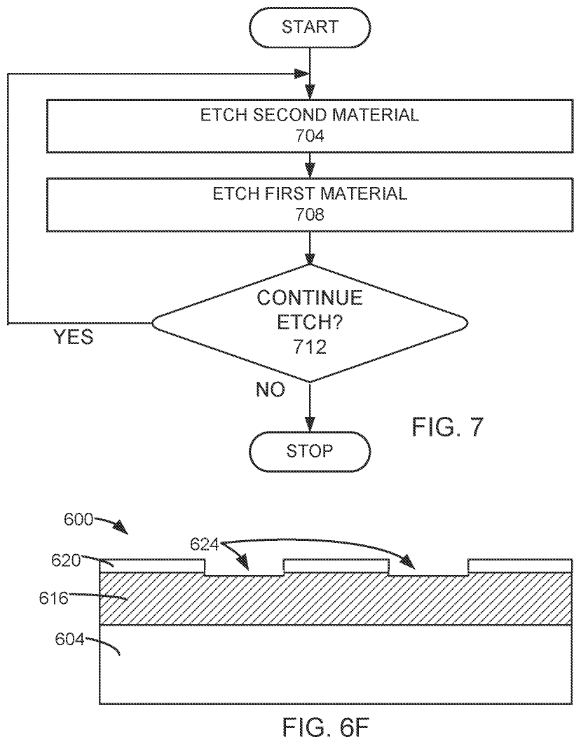

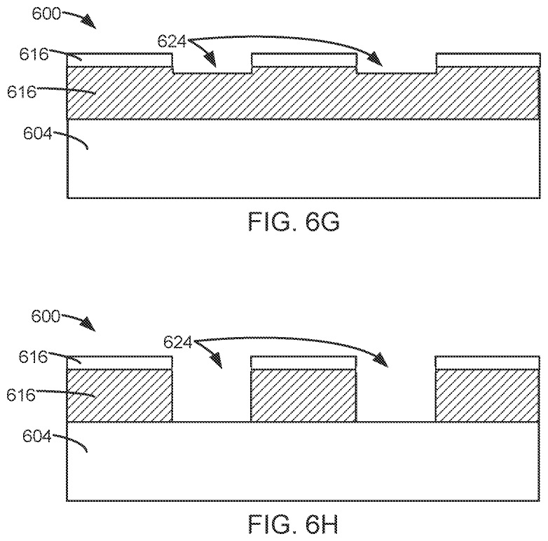

In another embodiment, the alloy layer may be used to provide a selective etch to form features. FIG. 5 is a high level flow chart of another embodiment. Various embodiments may have more or less steps. In addition, the steps may be performed in different orders or simultaneously. A first material is deposited (step 504). FIG. 6A is a schematic cross-sectional view of a stack 600 processed according to an embodiment. In this embodiment, the stack comprises a substrate 604 on which a first material layer 608 is over the substrate 604. In various embodiments, the first material layer 608 may be any material. These materials may be deposited by any method at any thickness. In this example, the first material is SnO₂. In this embodiment, the first material is deposited by atomic layer deposition or chemical vapor deposition to provide a thin conformal layer. In this embodiment, the first material layer 608 has a thickness of between 0.5 nm to 10 nm.

A second material is deposited on the first material (step 508). In various embodiments, the second material layer may be any material. This second materials may be deposited by any method at any thickness. FIG. 6B is a schematic cross-sectional view of a stack 600 after a second material layer 612 is deposited over the first material layer 608. In this example, the second material is TiO₂. In this embodiment, the second material is deposited by atomic layer deposition or chemical vapor deposition to provide a thin conformal layer. In this embodiment, the second material layer 612 has a thickness of between 0.5 nm to 10 nm.

The deposition of alternating layers of the first material layer 608 and the second material layer 612 is continued (step 512) for a plurality of cycles resulting in a stack with a plurality of alternating layers of the first material layer 608 and the second material layer 612. FIG. 6C is a schematic cross-sectional view of the stack 600 after a plurality of alternating layers of a first material layer 608 and a second material layer 612.

An alloy layer or alloy layers are formed between the first material layers 608 and the second material layers 612 (step 516). Any alloying process may be used to alloy the first material layer 608 and the second material layer 612. In this embodiment, heat is used to form an alloy layer between the first material layers 608 and the second material layers 612. In other embodiments, the first material layer 608 and second material layer 612 form an alloy without the addition of heat. FIG. 6D is a schematic cross-sectional view of the stack 600 after an alloy layer 616 is formed. The alloy is a titanium-silicon-oxide (Ti—Si-Ox) alloy.

A patterned mask is formed over the alloy layer 616 (step 520). The patterned mask may be of any possible material. In this embodiment, the patterned mask is a photoresist mask comprising at least one of a polymer photoresist and a metal containing photoresist. The patterned mask may comprise an underlayer comprising at least one of carbon such as amorphous carbon, spin-on-carbon (SOC). The patterned mask may also comprise an underlayer comprising at least one of silicon containing material such as spin-on-glass (SOG), SiO₂, silicon nitride (SiN), SiC, silicon oxycarbide (SiOC), and silicon oxycarbonitride (SiOCN). FIG. 6E is a schematic cross-sectional side view of a stack 600 after a patterned mask 620 has been formed over the alloy layer 616. Mask features 622 are formed in the patterned mask 620.

The alloy layer 616 is etched (step 524). In various embodiments, one of many different etch processes may be used. In this embodiment, a plasma formed from a nitrogen trifluoride (NF₃) gas is used to etch titanium oxide, but is not able to etch the titanium-tin-oxide alloy, since tin tetrafluoride (SnF₄) is not volatile. A plasma formed from H₂ is able to etch tin oxide, but not titanium-tin-oxide, since titanium tetrahydride (TiH₄) is not stable. In one embodiment, a plasma is formed from a gas of a mixture of NF₃ and H₂. The ratio of the flow rate of NF₃ to H₂ can be tuned in order to control the etch of the alloy layer 616.

In another embodiment, an etch of the alloy may be performed as a cyclical process. FIG. 7 is a more detailed flow chart of the etching of the alloy layer 616 in a cyclical process using etch cycles (step 524). Various embodiments may have more or less steps. In addition, the steps may be performed in different orders or simultaneously. The second material is etched (step 704). Various embodiments may have different etch processes. In this embodiment, a second chemistry of an NF₃ gas is formed into a plasma to etch away a top layer of titanium of the alloy layer 616 of titanium-tin-oxide. The second chemistry is used to selectively etch the second material with respect to the first material. The etch is self-limiting since the tin prevents further etching of the alloy layer. FIG. 6F is a schematic cross-sectional side view of a stack 600, where the second material has been etched. Etch features 624 are formed when a thin layer of titanium is etched.

The first material is etched (step 708). Various embodiments may have different etch processes. In this embodiment, a first chemistry of a H₂ gas is formed into a plasma to etch away a top layer of tin of the alloy layer 616 of titanium-tin-oxide. The first chemistry is used to selectively etch the first material with respect to the second material. The etch is self-limiting since the titanium prevents further etching of the alloy layer. FIG. 6G is a schematic cross-sectional side view of a stack 600, where the first material has been etched. Features 624 are etched deeper when a thin layer of tin is etched.

If the etch is not complete and is to be continued (step 712), then the process is repeated for another cycle. FIG. 6H is a cross-sectional schematic side view of the stack 600 after the features 624 have been completely etched.

Forming the alloy layer 616 and using the alloy layer 616 as a selective etch layer allows for controlled conformal etch. In an embodiment where the first material layer 608 and the second material layer 612 are deposited by atomic layer deposition or chemical vapor deposition, the first material layer 608 and the second material layer 612 are deposited as thin conformal layers. The first material layer 608 and the second material layer 612 are thin enough so that all of the first material layer 608 and all of the second material layer 612 are alloyed, instead of forming a nanolaminate of different material layers. Since this etch is self-limiting and etches only one atomic layer for each etch step, this process provides an atomic layer etch. Since the atomic layer etch is a chemical etch, instead of a physical etch, the resulting etch is highly conformal.

In other embodiments, the first material layer 608 and the second material layer 612 may be silicon and aluminum. Silicon oxide may be etched with a fluorine containing plasma. Aluminum oxide may be etched with a chlorine containing plasma.

In some embodiments, the first layers and the second layers may form nanolaminates of different layers. In other embodiments, the ratios of concentrations or thicknesses of the first material and the second material may be varied at different heights.

Uniform depositions that do not vary in thickness provide more uniform alloying. Thickness variations cause chemical variations. Since atomic layer deposition provides layers of uniform thickness, atomic layer deposition, would be preferred in some embodiments in the formation of thin uniform layers.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

1. A method for forming etched features in a layer of a first material, comprising:
depositing a layer of a second material over the layer of the first material;
forming an alloy layer of the first material and the second material between the layer of the first material and the layer of the second material; and
selectively etching the layer of the first material with respect to the alloy layer, using the alloy layer as a hardmask.

2. The method, as recited in claim 1, wherein the depositing the layer of the second material is by atomic layer deposition.

3. The method, as recited in claim 1, further comprising etching away the layer of the second material that is not alloyed.

4. The method, as recited in claim 1, wherein the layer of the first material is over a substrate and further comprising etching the substrate using the alloy layer as a hardmask.

5. The method, as recited in claim 1, wherein the alloy layer has a thickness of between 0.5 nm and 10 nm.

6. The method, as recited in claim 1, wherein the layer of the second material has a thickness of between 0.5 nm and 20 nm.

7. The method, as recited in claim 1, further comprising forming a patterned mask over the layer of the first material before depositing the layer of a second material.

8. The method, as recited in claim 7, wherein the patterned mask comprises at least one mask layer and at least one feature wherein the second material only contacts the first material at the at least one feature, and wherein the alloy layer is formed below the at least one feature and not below the at least one mask layer.

9. The method, as recited in claim 1, wherein the first material comprises silicon oxide and the second material comprises at least one of tin, tungsten, and platinum.

10. A method for etching a layer of a first material, comprising a plurality of cycles, wherein each cycle, comprises:
depositing a layer of a second material over the layer of the first material;
forming an alloy layer of the first material and the second material between the layer of the first material and the layer of the second material;
etching away the layer of the second material; and
etching away the alloy layer.

11. The method, as recited in claim 10, wherein the layer of the second material is deposited by atomic layer deposition.

12. The method, as recited in claim 10, wherein the alloy layer has a thickness of between 0.5 nm and 10 nm.

13. The method, as recited in claim 10, wherein the layer of the second material has a thickness of between 0.5 nm and 20 nm.

14. The method, as recited in claim 10, further comprising forming a patterned mask over the layer of the first material before depositing the layer of a second material, wherein the patterned mask comprises at least one mask layer and at least one feature wherein the second material only contacts the first material at the at least one feature, and wherein the alloy layer is formed below the at least one feature and not below the at least one mask layer.

15. The method, as recited in claim 10, wherein the first material comprises silicon oxide and the second material comprises titanium oxide.

16. A method for forming an alloy layer with features, comprising:
depositing an alloy layer comprising a plurality of cycles, wherein each cycle comprises:
depositing by atomic layer deposition a layer of a first material; and
depositing by atomic layer deposition a layer of a second material, wherein the layer of the first material and the layer of the second material form the alloy layer.

17. The method, as recited in claim 16, further comprising a plurality of etching cycles, wherein each etch cycle comprises:
etching the alloy layer with a second chemistry, wherein the second chemistry selectively etches the second material with respect to the first material; and
etching the alloy layer with a first chemistry, wherein the first chemistry selectively etches the first material with respect to the second material.

18. The method, as recited in claim 17, further comprising tuning ratios of etching the alloy layer with the first chemistry and etching the alloy layer with the second chemistry.

19. The method, as recited in claim 16, further comprising an etching step wherein the etching step comprises:
providing an etch gas comprising a mixture of a first chemistry and a second chemistry, wherein the first chemistry selectively etches the first material with respect to the second material wherein the second chemistry selectively etches the second material with respect to the first material; and
forming the etch gas into a plasma.
